(19) United States
(12) Patent Application Publication
(10) Pub. No.: US 2016/0005916 A1
(43) Pub. Date: Jan. 7, 2016

(54) Method of Making Photovoltaic Devices

(71) Applicant: FIRST SOLAR MALAYSIA SDN. BHD., Kulim (MY)

(72) Inventors: Jinbo Cao, Niskayuna, NY (US); Yong Liang, Niskayuna, NY (US); William Hullinger Huber, Niskayuna, NY (US); Sheng Xu, Shanghai (CN)

(73) Assignee: FIRST SOLAR MALAYSIA SDN. BHD., Kulim (MY)

(21) Appl. No.: 14/776,081

(22) PCT Filed: Mar. 14, 2014
(86) PCT No.: PCT/IB2014/001057

§ 371 Date: Sep. 14, 2015

(30) Foreign Application Priority Data
Mar. 14, 2013 (CN) 201310081875.4

(51) Int. Cl. H01L 31/18

(52) U.S. Cl. CPC H01L 31/1884; H01L 31/1828

(57) ABSTRACT

A method of making a photovoltaic device is presented. The method includes disposing a capping layer on a transparent conductive oxide layer, wherein the capping layer includes elemental magnesium, a magnesium alloy, a binary magnesium oxide, or combinations thereof. The method further includes disposing a window layer on the capping layer; and forming an interlayer between the transparent conductive oxide layer and the window layer, wherein the interlayer includes magnesium.

### BACKGROUND

The invention generally relates to method of making photovoltaic devices. More particularly, the invention relates to method of making photovoltaic devices that include an interlayer.

Thin film solar cells or photovoltaic (PV) devices typically include a plurality of semiconductor layers disposed on a transparent substrate, wherein one layer serves as a window layer and a second layer serves as an absorber layer. The window layer allows the penetration of solar radiation to the absorber layer, where the optical energy is converted to usable electrical energy. The window layer further functions to form a heterojunction (p-n junction) in combination with an absorber layer. Cadmium telluride/cadmium sulfide (CdTe/CdS) heterojunction-based photovoltaic cells are one such example of thin film solar cells, where CdS functions as the window layer.

However, thin film solar cells may have low conversion efficiencies. Thus, one of the main focuses in the field of photovoltaic devices is the improvement of conversion efficiency. Absorption of light by the window layer may be one of the phenomena limiting the conversion efficiency of a PV device. Thus, it is desirable to keep the window layer as thin as possible to help reduce optical losses by absorption. However, for most of the thin-film PV devices, if the window layer is too thin, a loss in performance can be observed due to low open circuit voltage (V_{OC}) and fill factor (FF). It is also desirable that the thin window layer maintain its structural integrity during the subsequent device fabrication steps, such that the interface between the absorber layer and the window layer contains negligible interface defect states.

Thus, there is a need for improved thin film photovoltaic devices configurations, and methods of manufacturing these.

### BRIEF DESCRIPTION OF THE INVENTION

Embodiments of the present invention are included to meet these and other needs. One embodiment is a method. The method includes disposing a capping layer on a transparent conductive oxide layer, wherein the capping layer includes elemental magnesium, a magnesium alloy, a binary magnesium oxide, or combinations thereof. The method further includes disposing a window layer on the capping layer; and forming an interlayer between the transparent conductive oxide layer and the window layer, wherein the interlayer includes magnesium. One embodiment is a method. The method includes disposing a capping layer on a transparent conductive oxide layer, wherein the capping layer includes elemental magnesium, a magnesium alloy, a binary magnesium oxide, or combinations thereof. The method further includes disposing a window layer on the capping layer, wherein the window layer includes cadmium and sulfur. The method further includes forming an interlayer between the transparent conductive oxide layer and the window layer, wherein the interlayer includes magnesium.

One embodiment is a method. The method includes disposing a capping layer on a buffer layer disposed on a transparent conductive oxide layer, wherein the capping layer includes a binary magnesium oxide. The method further includes disposing a window layer on the capping layer, wherein the window layer includes cadmium and sulfur. The method further includes forming an interlayer between the transparent conductive oxide layer and the window layer, wherein the interlayer includes magnesium. The method further includes disposing an absorber layer on the window layer.

### DRAWINGS

These and other features, aspects, and advantages of the present invention will become better understood when the following detailed description is read with reference to the accompanying drawings, wherein:

FIG. 1 is a schematic of a layer stack, according to some embodiments of the invention.

FIG. 2 is a schematic of a layer stack, according to some embodiments of the invention.

FIG. 3 is a schematic of a layer stack, according to some embodiments of the invention.

FIG. 4 is a schematic of a photovoltaic device, according to some embodiments of the invention.

FIG. 5 is a schematic of a photovoltaic device, according to some embodiments of the invention.

FIG. 6 is a schematic of a photovoltaic device, according to some embodiments of the invention.

FIG. 7 is a schematic of a photovoltaic device, according to some embodiments of the invention.

FIG. 8 is a schematic of a photovoltaic device, according to some embodiments of the invention.

FIG. 9 shows the performance parameters for photovoltaic devices, according to some embodiments of the invention.

FIG. 10A shows the x-ray photoelectron spectroscopy (XPS) depth profile of a photovoltaic device, according to a comparative example.

FIG. 10B shows the x-ray photoelectron spectroscopy (XPS) depth profile of a photovoltaic device, according to some embodiments of the invention.

FIG. 11 shows the performance parameters for photovoltaic devices, according to some embodiments of the invention.

### DETAILED DESCRIPTION

As discussed in detail below, some of the embodiments of the invention include method of making photovoltaic devices including an interlayer disposed between a transparent conductive oxide layer and a window layer. In some embodiments, the interlayer is disposed between a buffer layer and a window layer. In some embodiments, the interlayer is disposed between a transparent conductive oxide layer and a buffer layer.

Approximating language, as used herein throughout the specification and claims, may be applied to modify any quantitative representation that could permissibly vary without resulting in a change in the basic function to which it is related. Accordingly, a value modified by a term or terms, such as “about”, and “substantially” is not to be limited to the precise value specified. In some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

In the following specification and the claims, the singular forms “a”, “an” and “the” include plural referents unless the context clearly dictates otherwise. As used herein, the term “or” is not meant to be exclusive and refers to at least one of the referenced components (for example, a layer) being present and includes instances in which a combination of the referenced components may be present, unless the context clearly dictates otherwise.

The terms “transparent region” and “transparent conductive oxide layer” as used herein, refer to a region or a layer that allows an average transmission of at least 70% of incident electromagnetic radiation having a wavelength in a range from about 350 nm to about 850 nm.

As used herein, the term “layer” refers to a material disposed on at least a portion of an underlying surface in a continuous or discontinuous manner. Further, the term “layer” does not necessarily mean a uniform thickness of the disposed material, and the disposed material may have a uniform or a variable thickness. As used herein, the term “disposed on” refers to layers disposed directly in contact with each other or indirectly by having intervening layers therebetween, unless otherwise specifically indicated. The term “adjacent” as used herein means that the two layers are disposed contiguously and are in direct contact with each other.

In the present disclosure, when a layer is being described as “on” or “between” another layer or substrate, it is to be understood that the layers can either be directly contacting each other or have one (or more) layer or feature between the layers. Further, the term “on” describes the relative position of the layers to each other and does not necessarily mean “on top of” since the relative position above or below depends upon the orientation of the device to the viewer. Moreover, the use of “top,” “bottom,” “above,” “below,” and variations of these terms is made for convenience, and does not require any particular orientation of the components unless otherwise stated.

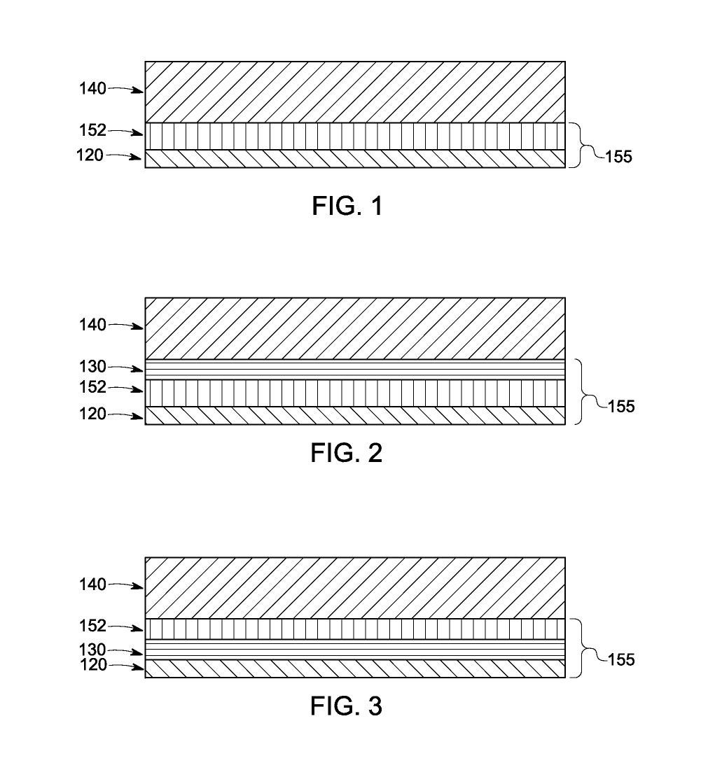

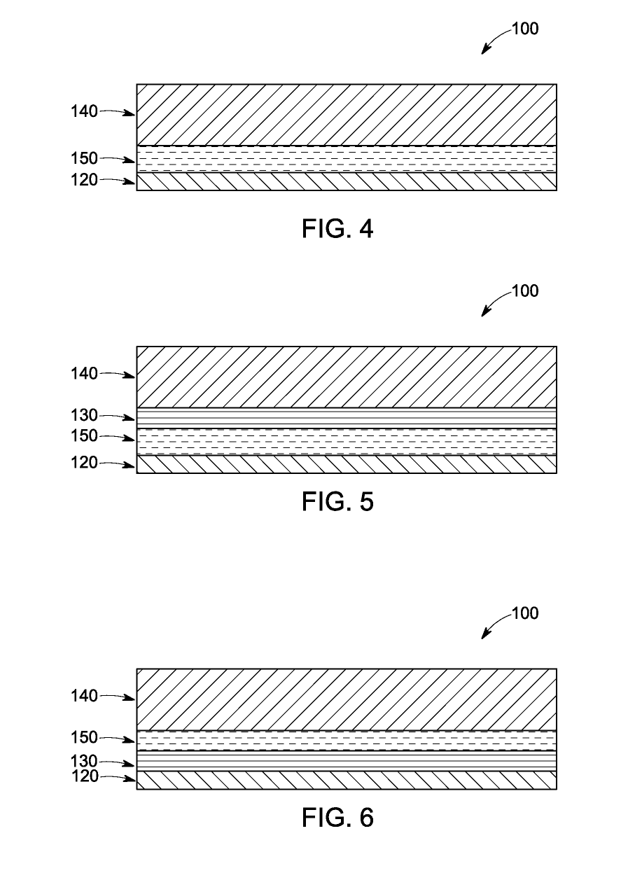

As discussed in detail below, some embodiments of the invention are directed to methods of making a photovoltaic device including an interlayer. A method of making a photovoltaic device 100, according to some embodiments of the invention, is illustrated in FIGS. 1-6. As illustrated in FIGS. 1-3, the method includes disposing a capping layer 152 on a transparent conductive oxide layer 120 to form a layer stack 155. The method further includes disposing a window layer 140 on the capping layer 152, as illustrated in FIGS. 1-3. The method further includes forming an interlayer 150 between the transparent conductive oxide layer 120 and the window layer 140, as illustrated in FIGS. 4-6.

The term “capping layer” as used herein refers to a layer in its as-deposited state, which has not been subjected to subsequent processing steps. The capping layer 152 includes elemental magnesium, a binary magnesium compound, a magnesium alloy, or combinations thereof. In certain embodiments, the capping layer 152 includes elemental magnesium, a binary magnesium oxide, a magnesium alloy, or combinations thereof.

The term “compound”, as used herein, refers to a macroscopically homogeneous material (substance) consisting of atoms or ions of two or more different elements in definite proportions, and at definite lattice positions. For example, magnesium, tin and oxygen have defined lattice positions in the crystal structure of a magnesium tin oxide compound, in contrast, for example, to tin-doped magnesium oxide where tin may be a dopant that is substitutionally inserted on magnesium sites, and not a part of the compound lattice. The term “binary magnesium compound” as used herein refers to a compound including magnesium and one other element. The term “binary magnesium oxide” as used herein refers to a compound including magnesium and oxygen. It should be noted however, that the compound may be further doped with one or more dopants. Thus, by way of example a binary magnesium oxide (MgO) may be further doped using a suitable dopant.

In some embodiments, the capping layer 152 has a thickness in a range from about 0.2 nanometers to about 200 nanometers. In some embodiments, the capping layer 152 has a thickness in a range from about 0.2 nanometers to about 100 nanometers. In some embodiments, the capping layer 152 has a thickness in a range from about 1 nanometer to about 20 nanometers.

The term “transparent conductive oxide layer” as used herein refers to a substantially transparent layer capable of functioning as a front current collector. In some embodiments, the transparent conductive oxide layer 120 includes a transparent conductive oxide (TCO). Non-limiting examples of transparent conductive oxides include cadmium tin oxide (Cd₂SnO₄ or CTO); indium tin oxide (ITO); fluorine-doped tin oxide (SnO:F or FTO); indium-doped cadmium-oxide; doped zinc oxide (ZnO), such as aluminum-doped zinc-oxide (ZnO:Al or AZO), indium-zinc oxide (IZO), and zinc tin oxide (ZnSnOₓ); or combinations thereof. Depending on the specific TCO employed and on its sheet resistance, the thickness of the transparent conductive oxide layer 120 may be in a range of from about 50 nm to about 600 nm, in one embodiment.

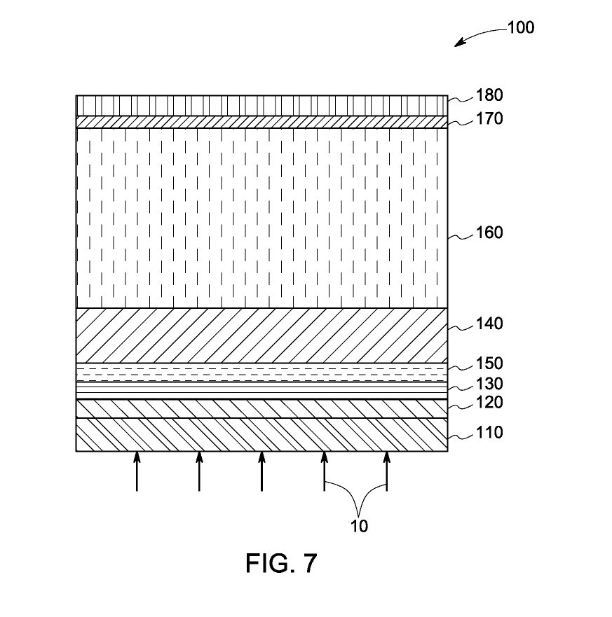

The term “window layer” as used herein refers to a semiconducting layer that is substantially transparent and forms a heterojunction with an absorber layer 160 (indicated in FIG. 7). Non-limiting exemplary materials for the window layer 140 include cadmium sulfide (CdS), indium III sulfide (In₂S₃), zinc sulfide (ZnS), zinc telluride (ZnTe), zinc selenide (ZnSe), cadmium selenide (CdSe), oxygenated cadmium sulfide (CdS:O), copper oxide (Cu₂O), zinc oxihydrate (ZnO:H), or combinations thereof. In certain embodiments, the window layer 140 includes cadmium sulfide (CdS). In certain embodiments, the window layer 140 includes oxygenated cadmium sulfide (CdS:O).

In some embodiments, as indicated in FIGS. 1 and 2, the method includes disposing the capping layer 152 directly in contact with the transparent conductive oxide layer 120. Further, in such instances, the method may include disposing the window layer 140 directly in contact with the capping layer 152 (as indicated in FIG. 1), or, alternatively disposing a buffer layer 130 on the capping layer, and then disposing the window layer on the buffer layer 130 (as indicated in FIG. 2).

The term “buffer layer” as used herein refers to a layer interposed between the transparent conductive oxide layer 120 and the window layer 140, wherein the layer 130 has a higher sheet resistance than the sheet resistance of the transparent conductive oxide layer 120. The buffer layer 130 is sometimes referred to in the art as a “high-resistivity transparent conductive oxide layer” or “HRT layer”. Non-limiting examples of suitable materials for the buffer layer 130 include tin dioxide (SnO₂), zinc tin oxide (zinc-stannate (ZTO)), zinc-doped tin oxide (SnO₂:Zn), zinc oxide (ZnO), indium oxide (In₂O₃), titanium oxide (TiO₂), or combinations thereof. In some embodiments, the thickness of the buffer layer 130 is in a range from about 50 nm to about 200 nm.

In some other embodiments, as indicated in FIG. 3, the method further includes disposing a buffer layer 130 on the transparent conductive oxide layer 120. In such instances, the method further includes disposing the capping layer 152 on the buffer layer 130. Further, in such instances, the capping layer 152 may be disposed directly in contact with the buffer layer 130 (as indicated in FIG. 3), or, alternatively may be disposed on an intervening layer (embodiment not shown), which in turn is disposed on the buffer layer 130. As noted, the method further includes disposing the window layer 140 on the capping layer 152, as indicated in FIG. 3.

The method further includes forming an interlayer 150 between the transparent conductive oxide layer 120 and the window layer 140, as indicated in FIGS. 4-6. The interlayer 150 includes magnesium. The term “magnesium” as used in this context refers to elemental magnesium, magnesium ion, or combinations thereof.

The step of forming the interlayer 150 may be effected prior to, simultaneously with, or after the step of disposing the window layer 140 on the capping layer 152. In some embodiments, the interlayer 150 may be formed prior to the step of disposing the window layer 140. In such instances, the method may further include a step of thermally processing the layer stack 155. The step of thermal processing may include, for example, annealing of the layer stack 155.

In some embodiments, the interlayer 150 may be formed simultaneously with the step of disposing the window layer 140. In some embodiments, the interlayer 150 may be formed after the step of disposing the window layer 140, for example, during the high-temperature absorber layer (e.g., CdTe) deposition step, during the cadmium chloride treatment step, during the p+-type layer formation step, during the back contact formation step, or combinations thereof.

In some embodiments, the step of interlayer 150 formation may further include intermixing of at least a portion of magnesium in the capping layer 152 with at least portion of the transparent conductive oxide layer 120 material, the buffer layer 130 material, or both. Without being bound by any theory, it is believed that during the window layer-deposition step or the post-deposition processing steps, one or both of recrystallization and chemical changes may occur in the capping layer 152, and a metal compound or a metal alloy may be formed in the resultant interlayer 150.

In some instances, the method may further result in the formation of oxides of magnesium and one or more of the metal species present in the transparent conductive oxide layer 120 or the buffer layer 130, during the interlayer 150 formation. In some instances, the method may result in formation of a metal compound including magnesium, tin, and oxygen during the interlayer 150 formation, for example, magnesium tin oxide. In some instances, the method may result in formation of a metal compound including magnesium, zinc, tin, and oxygen during the interlayer 150 formation, for example, magnesium zinc tin oxide.

In some embodiments, at least a portion of magnesium is present in the interlayer 150 in the form of a compound including magnesium and at least one of the metal species. Suitable non-limiting examples of the metal species include tin, indium, titanium, or combinations thereof. In some embodiments, the compound further includes oxygen, sulfur, selenium, tellurium, or combinations thereof. In some embodiments, the compound further includes zinc, cadmium, or combinations thereof. In certain embodiments, the interlayer includes a compound including magnesium, tin, and oxygen. In certain embodiments, the interlayer 150 includes a compound including magnesium, zinc, tin, and oxygen.

In some embodiments, at least a portion of magnesium is present in the interlayer 150 in the form of a ternary magnesium compound, a quaternary magnesium compound, or combinations thereof. The term “ternary magnesium compound” as used herein refers to a compound including magnesium and two other different elements. Thus, by way of example, in certain embodiments, the interlayer 150 includes magnesium tin oxide, magnesium tin sulfide, magnesium tin selenide, magnesium tin telluride, magnesium titanium oxide, magnesium titanium sulfide, magnesium titanium selenide, magnesium titanium telluride, magnesium indium oxide, magnesium indium sulfide, magnesium indium selenide, magnesium indium telluride, or mixtures thereof. In certain embodiments, the interlayer 150/250 includes magnesium stannate.

The term “quaternary magnesium compound” as used herein refers to a compound including magnesium and three other different elements. In some embodiments, the interlayer 150 includes a quaternary compound of magnesium and at least one of the metal species. Thus, by way of example, in certain embodiments, the interlayer 150 includes magnesium zinc tin oxide, magnesium zinc tin sulfide, magnesium zinc tin selenide, or mixtures thereof. In certain embodiments, the interlayer 150/250 includes magnesium zinc tin oxide.

In certain embodiments, the interlayer 150 includes magnesium tin oxide (sometimes also referred to as magnesium stannate) phase. Without being bound by any theory, it is believed that the formation of a compound including magnesium, tin, and oxygen (e.g., magnesium tin oxide or magnesium zinc tin oxide) may preclude diffusion of deleterious species from the transparent conductive oxide layer 120, the buffer layer 130, or both, to the junction-forming layers.

In some embodiments, at least a portion of magnesium is present in the interlayer in the form of a metal alloy. In some embodiments, the interlayer 150 includes a metal alloy of magnesium and at least one of tin, zinc, and cadmium. In certain embodiments, the interlayer includes a zinc magnesium alloy, for example, ZnₓMg₁₋ₓ, wherein x is a number greater than 0 and less than 1.

The interlayer 150 may be further characterized by the concentration of magnesium in the interlayer 150. In some embodiments, an atomic concentration of magnesium in the interlayer 150 may be substantially constant across the thickness of the interlayer 150. The term “substantially constant” as used herein means that the concentration of magnesium varies by less than about 5 percent across the thickness of the interlayer 150. In some other embodiments, magnesium may be compositionally graded across the thickness of the interlayer 150.

In some embodiments, an average atomic concentration of magnesium in the interlayer 150 is greater than about 10 percent. In some embodiments, an average atomic concentration of magnesium in the interlayer 150 is greater than about 50 percent. In some embodiments, an average atomic concentration of magnesium in the interlayer 150 is in a range from about 10 percent to about 99 percent. The term “atomic concentration” as used herein refers to the average number of atoms per unit volume. As noted earlier, the interlayer 150 may further include cadmium, sulfur, tin, oxygen, fluorine, or combinations thereof.

The interlayer 150 may be further characterized by a thickness. In some embodiments, the interlayer 150 has a thickness in a range from about 0.2 nanometers to about 200 nanometers. In some embodiments, the interlayer 150 has a thickness in a range from about 0.2 nanometers to about 100 nanometers. In some embodiments, the interlayer 150 has a thickness in a range from about 1 nanometer to about 20 nanometers. In some embodiments, it may be desirable to have a thin interlayer, such that there are minimal optical losses in the interlayer 150 due to absorption.

As described earlier, the thickness of the window layer 140 is typically desired to be minimized in a photovoltaic device to achieve high efficiency. With the presence of the interlayer 150, the thickness of the window layer 140 (e.g., CdS layer) may be reduced to improve the performance of the photovoltaic device. Moreover, the photovoltaic device may achieve a reduction in cost of production because of the use of lower amounts of CdS.

As noted, a method of making a photovoltaic device is presented. In some embodiments, the photovoltaic device includes a “superstrate” configuration of layers. FIG. 7 illustrates an exemplary embodiment of a photovoltaic according to some embodiments of the invention. Referring now to FIG. 7, the photovoltaic device 100 further includes a support 110, and the transparent conductive oxide layer 120 (sometimes referred to in the art as a front contact layer) is disposed on the support 110. As further illustrated in FIG. 7, in such embodiments, the solar radiation 10 enters from the support 110, and after passing through the transparent conductive oxide layer 120, the buffer layer 130 (if present), the interlayer 150, and the window layer 140, enters the absorber layer 160, where the conversion of electromagnetic energy of incident light (for instance, sunlight) to electron-hole pairs (that is, to free electrical charge) occurs. The photovoltaic device may further include a p+-type semiconductor layer 170 and a back contact layer 180, as indicated in FIG. 7.

The composition of the transparent conductive oxide layer 120, the buffer layer 130, the window layer 140, and the interlayer 150 have been described earlier. The support 110 is transparent over the range of wavelengths for which transmission through the support 110 is desired. In some embodiments, the support 110 includes a silica, borosilicate glass, soda-lime glass, polyimide, or combinations thereof. In some embodiments certain other layers may be disposed between the transparent conductive oxide layer 120 and the support 110, such as, for example, an anti-reflective layer or a barrier layer (not shown).

The term “absorber layer” as used herein refers to a semiconducting layer wherein the solar radiation is absorbed. In some embodiment, the absorber layer 160 includes a p-type semiconductor material. In some embodiments, a photoactive material is used for forming the absorber layer 160. Suitable photoactive materials include cadmium telluride (CdTe), cadmium zinc telluride (CdZnTe), cadmium magnesium telluride (CdMgTe), cadmium manganese telluride (CdMnTe), cadmium sulfur telluride (CdSTe), cadmium selenium telluride (CdSeTe), zinc telluride (ZnTe), copper indium disulfide (CIS), copper indium diselenide (CISe), copper indium gallium sulfide (CIGS), copper indium gallium diselenide (CIGSe), copper indium gallium sulfur selenium (CIGSSe), copper indium gallium aluminum sulfur selenium (Cu(In,Ga,Al)(S,Se)₂), copper zinc tin sulfide (CZTS), or combinations thereof. The above-mentioned photoactive semiconductor materials may be used alone or in combination. Further, these materials may be present in more than one layer, each layer having different type of photoactive material, or having combinations of the materials in separate layers. In certain embodiments, the absorber layer 160 includes cadmium telluride (CdTe). In certain embodiments, the absorber layer 160 includes p-type cadmium telluride (CdTe).

In some embodiments, the window layer 140, the absorber layer 160, or both the layers may contain oxygen. Without being bound by any theory, it is believed that the introduction of oxygen to the window layer 140 (e.g., the CdS layer) may result in improved device performance. In some embodiments, the amount of oxygen is less than about 20 atomic percent. In some instances, the amount of oxygen is between about 1 atomic percent to about 10 atomic percent. In some instances, for example in the absorber layer 160, the amount of oxygen is less than about 1 atomic percent. Moreover, the oxygen concentration within the window layer 140, the absorber layer 160, or both the layers may be substantially constant or compositionally graded across the thickness of the respective layer.

In some embodiments, the window layer 140 and the absorber layer 160 may be doped with a p-type dopant or an n-type dopant to form a heterojunction. As used in this context, a heterojunction is a semiconductor junction that is composed of layers of dissimilar semiconductor material. These materials usually have non-equal band gaps. As an example, a heterojunction can be formed by contact between a layer or region of one conductivity type with a layer or region of opposite conductivity, e.g., a “p-n” junction.

In some embodiments, the window layer 140 includes an n-type semiconductor material. In such instances, the absorber layer 160 may be doped to be p-type and the window layer 140 and the absorber layer 160 may form an “n-p” heterojunction. In some embodiments, the window layer 140 may be doped to be n-type and the absorber layer 160 may be doped such that it effectively forms an n-i-p configuration, using a p+-semiconductor layer on the backside of the absorber layer 160.

The term “p+-type semiconductor layer” as used herein refers to a semiconductor layer having an excess mobile p-type carrier or hole density compared to the p-type charge carrier or hole density in the absorber layer 160. In some embodiments, the p+-type semiconductor layer has a p-type carrier density in a range greater than about 1×10¹⁶ per cubic centimeter. The p+-type semiconductor layer 170 may be used as an interface between the absorber layer 160 and the back contact layer 180, in some embodiments.

In some embodiments, the p+-type semiconductor layer 170 includes a heavily doped p-type material including amorphous Si:H, amorphous SiC:H, crystalline Si, microcrystalline Si:H, microcrystalline SiGe:H, amorphous SiGe:H, amorphous Ge, microcrystalline Ge, GaAs, BaCuSF, BaCuSeF, BaCuTeF, LaCuOS, LaCuOSe, LaCuOTe, LaSrCuOS, LaCuOSe_{0.6}Te_{0.4}, BiCuOSe, BiCaCuOSe, PrCuOSe, NdCuOS, Sr₂Cu₂ZnO₂S₂, Sr₂CuGaO₃S, (Zn,Co,Ni)Oₓ, or combinations thereof. In another embodiment, the p+-type semiconductor layer 170 includes a p+-doped material including zinc telluride, magnesium telluride, manganese telluride, beryllium telluride, mercury telluride, arsenic telluride, antimony telluride, copper telluride, or combinations thereof. In some embodiments, the p+-doped material further includes a dopant including copper, gold, nitrogen, phosphorus, antimony, arsenic, silver, bismuth, sulfur, sodium, or combinations thereof.

In some embodiments, the photovoltaic device 100 further includes a back contact layer 180, as indicated in FIG. 7. In some embodiments, the back contact layer 180 is disposed directly on the absorber layer 160 (embodiment not shown). In some other embodiments, the back contact layer 180 is disposed on the p+-type semiconductor layer 170 disposed on the absorber layer 160, as indicated in FIG. 7.

In some embodiments, the back contact layer 180 includes gold, platinum, molybdenum, tungsten, tantalum, titanium, palladium, aluminum, chromium, nickel, silver, graphite, or combinations thereof. The back contact layer 180 may include a plurality of layers that function together as the back contact.

In some embodiments, another metal layer (not shown), for example, aluminum, may be disposed on the back contact layer 180 to provide lateral conduction to the outside circuit. In certain embodiments, a plurality of metal layers (not shown), for example, aluminum and chromium, may be disposed on the back contact layer 180 to provide lateral conduction to the outside circuit. In certain embodiments, the back contact layer 180 may include a layer of carbon, such as, graphite deposited on the absorber layer 160, followed by one or more layers of metal, such as the metals described above.

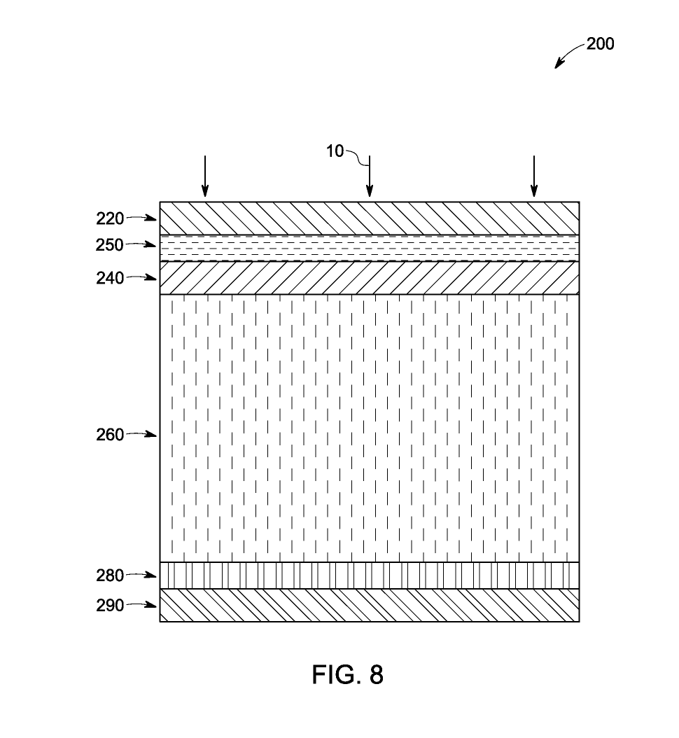

In alternative embodiments, as illustrated in FIG. 8, a method of making a photovoltaic device 200 including a “substrate” configuration is presented. The photovoltaic device 200 includes a back contact layer 280 disposed on a support 290. Further, an absorber layer 260 is disposed on the back contact layer 280. A window layer 240 is disposed on the absorber layer 260 and an interlayer 250 is disposed on the window layer 240. A transparent conductive oxide layer 220 is further disposed on the interlayer 250, as indicated in FIG. 8. As illustrated in FIG. 8, in such embodiments, the solar radiation 10 enters from the transparent conductive oxide layer 220 and after passing through the interlayer 250 and the window layer 240, enters the absorber layer 260, where the conversion of electromagnetic energy of incident light (for instance, sunlight) to electron-hole pairs (that is, to free electrical charge) occurs.

In some embodiments, the composition of the layers illustrated in FIG. 8, such as, the substrate 210, the transparent conductive oxide layer 220, the window layer 240, the interlayer 250, the absorber layer 260, and the back contact layer 280 may have the same composition as described above in FIG. 7 for the superstrate configuration.

As understood by a person skilled in the art, the sequence of disposing the layers or the whole device may depend on a desirable configuration, for example, “substrate” or “superstrate” configuration of the device. Further, the sequence of disposing the layers will depend on the device configuration. In certain embodiments, a method for making a photovoltaic device 100 in a superstrate configuration is described, wherein the device configuration includes a transparent conductive oxide layer, a buffer layer, and an interlayer stack.

Referring again to FIG. 7, in some embodiments, the method includes disposing the transparent conductive oxide layer 120 on a support 110 by any suitable technique, such as sputtering, chemical vapor deposition, spin coating, spray coating, or dip coating. In some embodiments, a buffer layer 130 may be deposited on the transparent conductive oxide layer 120, as indicated in FIG. 7 using sputtering.

As noted earlier, and with reference to FIG. 3, the method further includes disposing a capping layer 152 on the buffer layer 130. The capping layer 152 may be disposed using a suitable deposition technique, such as, for example, sputtering, atomic layer deposition, or combinations thereof. In certain embodiments, the method includes disposing the capping layer 152 by atomic layer deposition (ALD). In certain embodiments, the method includes disposing the capping layer 152 by sputtering.

The method further includes disposing a window layer 140 on the capping layer 152, as indicated in FIG. 3. Non-limiting examples of the deposition methods for the window layer 140 include one or more of close-space sublimation (CSS), vapor transport deposition (VTD), sputtering (for example, direct current pulse sputtering (DCP), electro-chemical deposition (ECD), and chemical bath deposition (CBD). The method further includes forming an interlayer 150 between the buffer layer 130 and the window layer 140, as indicated in FIG. 7. The interlayer composition and configuration are as described earlier.

The method further includes disposing an absorber layer 160 on the window layer 140. In some embodiments, the absorber layer 160 may be deposited using a suitable method, such as, close-space sublimation (CSS), vapor transport deposition (VTD), ion-assisted physical vapor deposition (IAPVD), radio frequency or pulsed magnetron sputtering (RFS or PMS), plasma enhanced chemical vapor deposition (PECVD), or electrochemical deposition (ECD).

In some embodiments, a series of post-forming treatments may be further applied to the exposed surface of the absorber layer 160. These treatments may tailor the functionality of the absorber layer 160 and prepare its surface for subsequent adhesion to the back contact layer(s) 180. For example, the absorber layer 160 may be annealed at elevated temperatures for a sufficient time to create a quality p-type layer. Further, the absorber layer 160 may be treated with a passivating agent (e.g., cadmium chloride) and a tellurium-enriching agent (for example, iodine or an iodide) to form a tellurium-rich region in the absorber layer 160. Additionally, copper may be added to the absorber layer 160 in order to obtain a low-resistance electrical contact between the absorber layer 160 and a back contact layer(s) 180.

In some embodiments, a p+-type semiconducting layer 170 may be further disposed on the absorber layer 160 by depositing a p+-type material using any suitable technique, for example PECVD or sputtering. In an alternate embodiment, as mentioned earlier, a p+-type semiconductor region may be formed in the absorber layer 160 by chemically treating the absorber layer 160 to increase the carrier density on the back-side (side in contact with the metal layer and opposite to the window layer) of the absorber layer 160 (for example, using iodine and copper). In some embodiments, a back contact layer 180, for example, a graphite layer may be deposited on the p+-type semiconductor layer 170, or directly on the absorber layer 160 (embodiment not shown). A plurality of metal layers may be further deposited on the back contact layer 180.

One or more of the window layer 140, the absorber layer 160, the back contact layer 180, or the p+-type layer 170 (optional) may be further heated or subsequently treated (for example, annealed) after deposition to manufacture the photovoltaic device 100.

### EXAMPLES

### Comparative Example 1

### Method of Manufacturing a Cadmium Telluride Photovoltaic Device, without an Interlayer

A cadmium telluride photovoltaic device was made by depositing several layers on a cadmium tin oxide (CTO) transparent conductive oxide (TCO)-coated substrate. The substrate was a 1.4 millimeters thick PVN++ glass, which was coated with a CTO transparent conductive oxide layer and a thin high resistance transparent zinc tin oxide (ZTO) buffer layer. The window layer containing cadmium sulfide (CdS:O, 5 molar % oxygen in the CdS layer) was then deposited on the ZTO layer by DC sputtering followed by deposition of cadmium telluride (CdTe) layer at 550° C., and back contact formation.

### Example 1

### Method of Manufacturing a Cadmium Telluride Photovoltaic Device Including an Interlayer Between the Buffer Layer and the CdS Layer

The method of making the photovoltaic device was similar to the Comparative Example 1, except a 3 nanometers thick or a 6 nanometers thick magnesium (Mg) capping layer was deposited by sputtering on the ZTO buffer layer, prior to the deposition of the CdS layer. An interlayer including Mg was formed between the buffer layer and the CdS layer.

### Example 2

### Method of Manufacturing a Cadmium Telluride Photovoltaic Device Including an Interlayer Between the TCO Layer and the CdS Layer

The method of making the photovoltaic device was similar to the Comparative Example 1, except a 3 nanometers thick elemental magnesium (Mg) capping layer was directly deposited by sputtering on the CTO layer, prior to the deposition of the CdS layer. An interlayer including Mg was formed between the CTO layer and the CdS layer. In this example a ZTO buffer layer was not deposited.

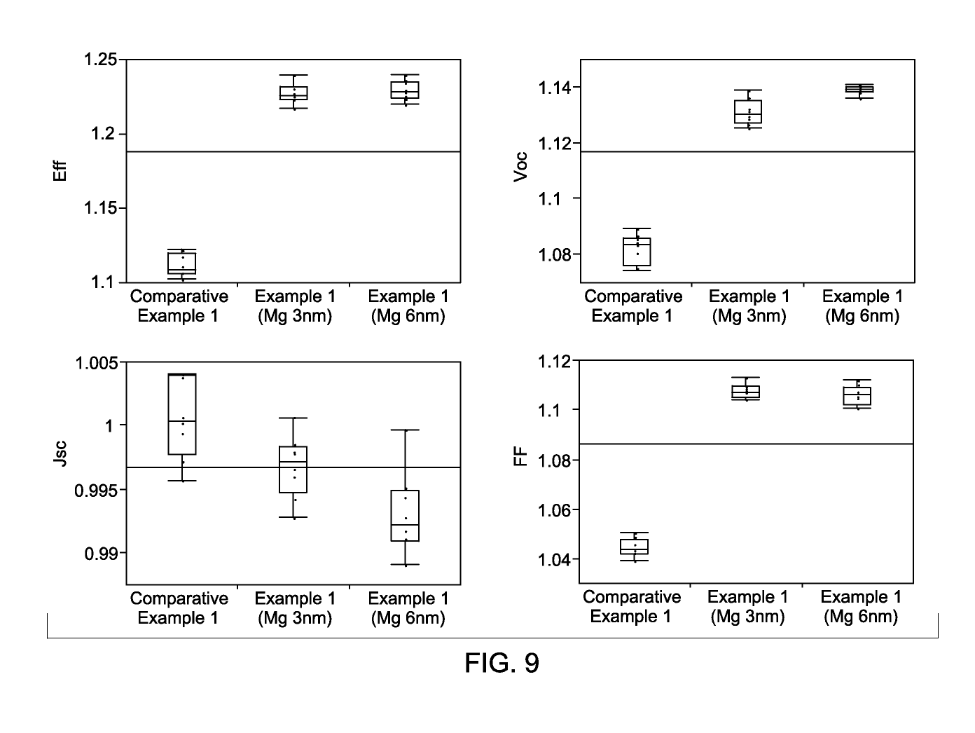

FIG. 9 illustrates the device performance parameters (normalized with respect to Comparative Example 1) for devices with and without an interlayer. As illustrated in FIG. 9, the device performance parameters showed improvement for the devices with an interlayer (Example 1) when compared to the device without the interlayer (Comparative Example 1).

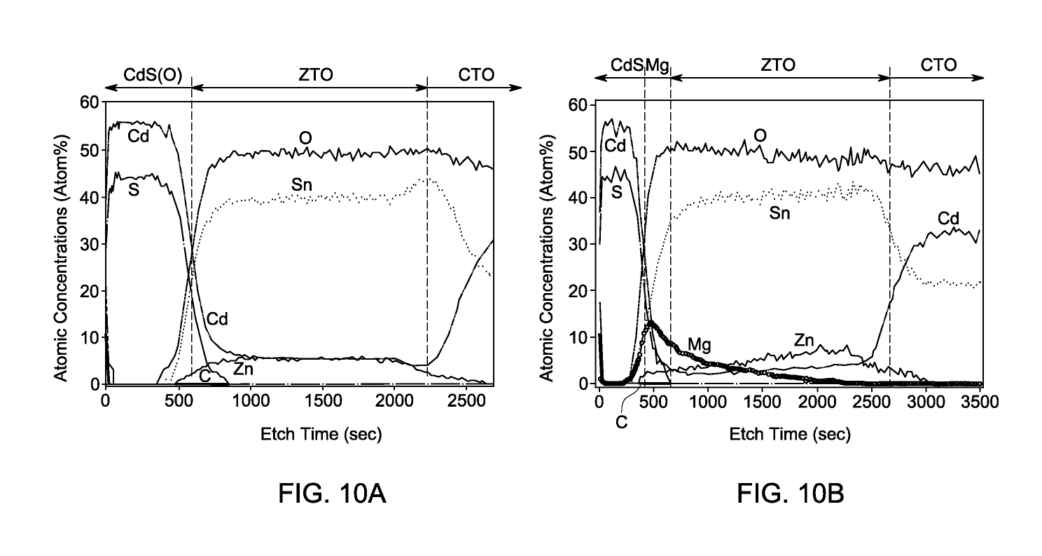

FIG. 10A shows the x-ray photoelectron spectroscopy (XPS) depth profiles of a photovoltaic device without an interlayer (Comparative Example 1). FIG. 10B shows the x-ray photoelectron spectroscopy (XPS) depth profiles of a photovoltaic device with an interlayer (Example 1). As illustrated in FIG. 10B, the XPS depth profile indicates formation of an interlayer between ZTO and CdS in Example 1, wherein the interlayer includes magnesium, tin, and oxygen. The XPS profiles also seem to suggest the presence of zinc and cadmium in the interlayer.

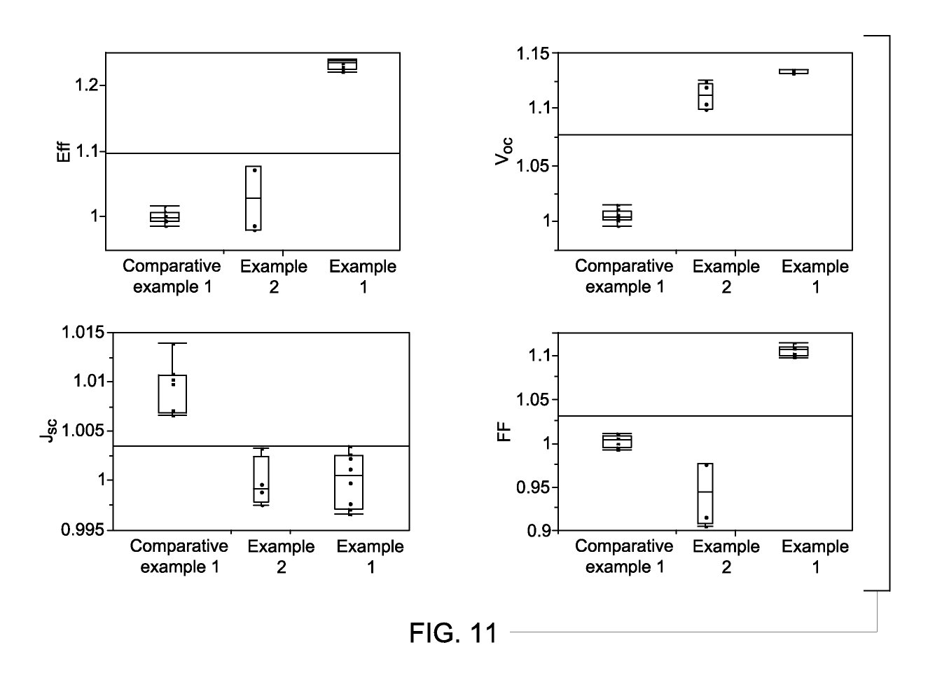

FIG. 11 illustrates the device performance parameters (normalized with respect to Comparative Example 1) for devices with and without an interlayer. As illustrated in FIG. 11, the device performance parameters showed improvement for the devices with an interlayer (Examples 1 and 2) when compared to the device without the interlayer (Comparative Example 1). Further, the device with an interlayer deposited on the buffer layer (Example 1) showed improved performance parameters when compared to the device with an interlayer deposited on the CTO layer (Example 2).

The appended claims are intended to claim the invention as broadly as it has been conceived and the examples herein presented are illustrative of selected embodiments from a manifold of all possible embodiments. Accordingly, it is the Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of” Where necessary, ranges have been supplied; those ranges are inclusive of all sub-ranges there between. It is to be expected that variations in these ranges will suggest themselves to a practitioner having ordinary skill in the art and where not already dedicated to the public, those variations should where possible be construed to be covered by the appended claims. It is also anticipated that advances in science and technology will make equivalents and substitutions possible that are not now contemplated by reason of the imprecision of language and these variations should also be construed where possible to be covered by the appended claims.

1. A method, comprising:
(a) disposing a capping layer on a transparent conductive oxide layer, wherein the capping layer comprises elemental magnesium, a magnesium alloy, a binary magnesium oxide, or combinations thereof;
(b) disposing a window layer on the capping layer; and
(c) forming an interlayer between the transparent conductive oxide layer and the window layer, wherein the interlayer comprises magnesium.

2. The method of claim 1, wherein the step (a) comprises disposing the capping directly in contact with the transparent conductive oxide layer.

3. The method of claim 2, further comprising disposing a buffer layer on the capping layer before the step (b).

4. The method of claim 1, further comprising disposing a buffer layer on the transparent conductive oxide layer, and wherein the step (a) comprises disposing the capping layer on the buffer layer.

5. The method of claim 1, wherein the transparent conductive oxide layer comprises cadmium tin oxide, zinc tin oxide, indium tin oxide, fluorine-doped tin oxide, indium-doped cadmium-oxide, doped zinc oxide, or combinations thereof.

6. The method of claim 4, wherein the buffer layer comprises tin dioxide, zinc oxide, indium oxide, zinc tin oxide, or combinations thereof.

7. The method of claim 1, wherein the window layer comprises cadmium sulfide, oxygenated cadmium sulfide, zinc sulfide, cadmium zinc sulfide, cadmium selenide, indium selenide, indium sulfide, or combinations thereof.

8. The method of claim 1, further comprising disposing an absorber layer on the window layer.

9. The method of claim 8, wherein the absorber layer comprises cadmium telluride, cadmium zinc telluride, cadmium sulfur telluride, cadmium selenium telluride, cadmium manganese telluride, cadmium magnesium telluride, copper indium sulfide, copper indium gallium selenide, copper indium gallium sulfide, or combinations thereof.

10. The method of claim 1, wherein the capping layer has a thickness in a range from about 0.2 nanometers to about 200 nanometers.

11. The method of claim 1, wherein the step of forming the capping layer comprises evaporation, atomic layer deposition, sputtering, or combinations thereof.

12. The method of claim 1, wherein the steps (b) and (c) are effected simultaneously.

13. The method of claim 1, wherein the steps (b) and (c) are effected sequentially.

14. The method of claim 1, wherein the interlayer further comprises tin, sulfur, oxygen, zinc, cadmium, or combinations thereof.

15. The method of claim 1, wherein the interlayer comprises a magnesium alloy, a compound comprising magnesium and tin, or combinations thereof.

16. A method, comprising:
(a) disposing a capping layer on a transparent conductive oxide layer, wherein the capping layer comprises elemental magnesium, a magnesium alloy, a binary magnesium oxide, or combinations thereof;
(b) disposing a window layer on the capping layer, wherein the window layer comprises cadmium and sulfur; and
(c) forming an interlayer between the transparent conductive oxide layer and the window layer, wherein the interlayer comprises magnesium.

17. The method of claim 1, wherein the step (a) comprises disposing the capping directly in contact with the transparent conductive oxide layer.

18. The method of claim 1, further comprising disposing a buffer layer on the transparent conductive oxide layer, and wherein the step (a) comprises disposing the capping layer on the buffer layer.

19. The method of claim 16, wherein the interlayer comprises a magnesium alloy, a compound comprising magnesium and tin, or combinations thereof.

20. A method, comprising:
(a) disposing a capping layer on a buffer layer disposed on a transparent conductive oxide layer, wherein the capping layer comprises a binary magnesium oxide;
(b) disposing a window layer on the capping layer, wherein the window layer comprises cadmium and sulfur;
(c) forming an interlayer between the transparent conductive oxide layer and the window layer, wherein the interlayer comprises magnesium; and
(d) disposing an absorber layer on the window layer.
